(19) United States
(12) Patent Application Publication
(10) Pub. No.: US 2018/0138522 A1
(43) Pub. Date: May 17, 2018

(54) LASER ABLATION OF WAVELENGTH TRANSPARENT MATERIAL WITH MATERIAL MODIFICATION

(71) Applicant: Applied Materials, Inc., Santa Clara, CA (US)

(72) Inventors: Giback PARK, Sosa-gu, Buncheon-si, Gyeonggi-do (KR); Michael Yu-Tak YOUNG, Cupertino, CA (US); Byung-Sung Leo KWAK, Portland, OR (US); Jeffrey L. FRANKLIN, Albuquerque, NM (US); Kyu CHO II, Santa Clara, CA (US)

(21) Appl. No.: 15/572,115

(22) PCT Filed: May 11, 2016
(86) PCT No.: PCT/US2016/031935

§ 371 Date: Nov. 6, 2017

Related U.S. Application Data
(60) Provisional application No. 62/159,865, filed on May 11, 2015.

(51) Int. Cl. H01M 6/40; H01S 5/183; H01S 5/20; H01M 10/052

(52) U.S. Cl. CPC H01M 6/40; H01S 5/183; H01M 10/0436; H01M 10/052; H01S 5/20

(57) ABSTRACT

A method of fabricating electrochemical devices may comprise: providing a layer of dielectric material on a metal electrode; enhancing light absorption in the layer of dielectric material within the visible and near UV range, forming a layer of enhanced dielectric material; and laser ablating substantially all of the enhanced dielectric material in select areas of the layer using a laser with a wavelength in the visible and near UV range, wherein the laser ablating leaves the metal electrode substantially intact. In some embodiments, the layer may be provided engineered for higher laser light absorption within the visible and near ultraviolet range, without the need for enhancing. An electrochemical device may comprise: a substrate; a stack of active device layers formed on the substrate; and an encapsulation layer covering the stack, engineered to strongly absorb laser light within the visible and near ultraviolet range.

### CROSS-REFERENCE TO RELATED APPLICATIONS

This application claims the benefit of U.S. Provisional Application No. 62/159,865 filed May 11, 2015, incorporated in its entirety herein,

### FIELD

Embodiments of the present disclosure relate generally to methods for manufacturing microelectronic and electrochemical devices, and more specifically, although not exclusively, to modification of encapsulation and dielectric materials for improved laser ablation selectivity to underlying metal layers in the manufacturing of thin film batteries.

### BACKGROUND

In microelectronics and electrochemical device fabrication, dielectric layer(s) are frequently used in between metallization layers and also as part of encapsulation layers. Using laser ablation to drill vias or holes in dielectric layer(s), and stop precisely on metallization layer(s), can be very challenging, and undesirable damage to, or even removal of, the metallization layers and metal splatter and redeposition may be an undesirable side effect of the ablation process—reducing the manufacturing yield of devices. There is a need for improved dielectric materials and laser ablation processes to improve the yield.

### SUMMARY

In some embodiments, laser light absorption within the visible and near UV part of the spectrum may be enhanced for encapsulation and dielectric materials, such as parylene and alumina, which ordinarily are transparent within this part of the spectrum, to improve selectivity of removal by laser ablation of a portion of a layer of the encapsulation/dielectric material over a metallization layer, by using one or more of: (1) UV exposure of the encapsulation/dielectric layer prior to laser ablation; (2) inclusion of dyes and similar light absorbing materials into the encapsulation/dielectric material; (3) formation of an encapsulation/dielectric layer with a compositional gradient. Encapsulation/dielectric layers modified as above may be incorporated into electrochemical devices such as solid state thin film batteries (TFBs). Methods for fabricating electrochemical devices may utilize material modification for encapsulation/dielectric layers as described herein.

According to some embodiments, a method of fabricating electrochemical devices may comprise: providing a layer of dielectric material on a metal electrode; enhancing light absorption in the layer of dielectric material within the visible and near UV range, forming a layer of enhanced dielectric material; and laser ablating substantially all of the enhanced dielectric material in select areas of the layer using a laser with a wavelength in the visible and near UV range, wherein the laser ablating leaves the metal electrode substantially intact.

According to some embodiments, a method of fabricating electrochemical devices may comprise: providing a layer of dielectric material on a metal electrode, the layer being engineered for higher laser light absorption within the visible and near ultraviolet range; and laser ablating substantially all of the dielectric material in select areas of the layer using a laser with a wavelength in the visible and near UV range, wherein the laser ablating leaves the metal electrode substantially intact.

According to some embodiments, an electrochemical device may comprise: a substrate; a stack of device layers formed on the substrate, the stack comprising a cathode current collector layer, a cathode layer, an electrolyte layer, an anode layer and an anode current collector layer; and an encapsulation layer covering the stack, the encapsulation layer being engineered to strongly absorb laser light within the visible and near ultraviolet range.

### BRIEF DESCRIPTION OF THE DRAWINGS

These and other aspects and features of the present disclosure will become apparent to those ordinarily skilled in the art upon review of the following description of specific embodiments in conjunction with the accompanying figures, wherein:

FIGS. 1 & 2 show a schematic representation of an undesirable laser ablation result for an encapsulation layer covering an electrode;

FIGS. 3 & 4 show a schematic representation of a desirable laser ablation result for an encapsulation layer covering an electrode, according to some embodiments;

FIG. 5 is a schematic representation of a pre-ablation UV exposure of an encapsulation layer covering an electrode, according to some embodiments;

FIG. 6 shows a plot of light attenuation against UV dose for a Parylene-C encapsulation layer, according to some embodiments;

FIG. 7 is a schematic representation of an encapsulation layer, with a compositional gradient to improve laser energy absorption, covering an electrode, according to some embodiments;

FIG. 8 is a cross-sectional representation of a first example of a TFB device on a thin substrate for a thin film battery, according to some embodiments; and

FIG. 9 is a cross-sectional representation of a second example of a TFB device on a thin substrate for a thin film battery, according to some embodiments.

### DETAILED DESCRIPTION

Embodiments of the present disclosure will now be described in detail with reference to the drawings, which are provided as illustrative examples of the disclosure so as to enable those skilled in the art to practice the disclosure. The drawings provided herein include representations of devices and device process flows which are not drawn to scale. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. In the present disclosure, an embodiment showing a singular component should not be considered limiting; rather, the disclosure is intended to encompass other embodiments including a plurality of the same component, and vice-versa, unless explicitly stated otherwise herein. Moreover, it is not intended for any term in the present disclosure to be ascribed an uncommon or special meaning unless explicitly set forth as such. Further, the present disclosure encompasses present and future known equivalents to the known components referred to herein by way of illustration.

In microelectronics and electrochemical device fabrication, dielectric layer(s) are frequently used in between metallization layers and also as part of encapsulation layers.

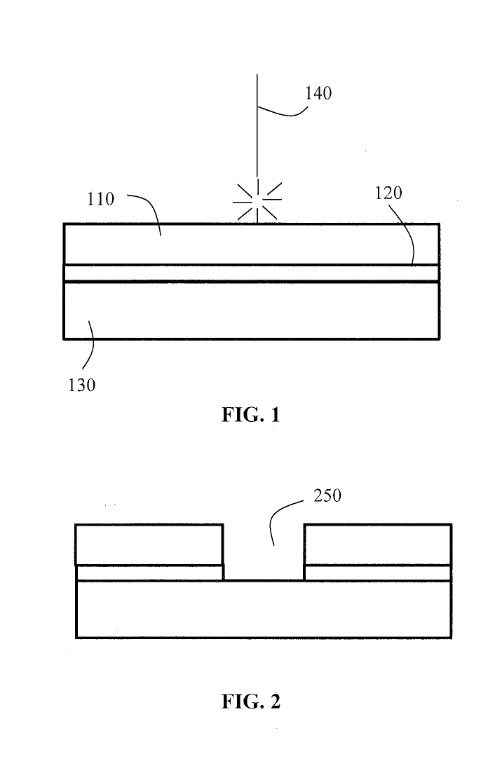

Using laser ablation to drill vias or holes in dielectric layer(s), and stop precisely on metallization layer(s), can be very challenging, and undesirable damage to, or even removal of, the metallization layers and metal splatter and redeposition may be an undesirable side effect of the ablation process—reducing the manufacturing yield of devices. FIGS. 1 & 2 show a schematic representation of an undesirable laser ablation result for an encapsulation/dielectric layer 110 covering an electrode/metal layer 120—the underlying metal layer 120 has been mostly ablated by the laser 140 during the process for exposure of the electrode by laser ablation of an area of the encapsulation/dielectric layer 110; the via 250 has been opened, in some cases, all the way through to the substrate/underlying layers 130.

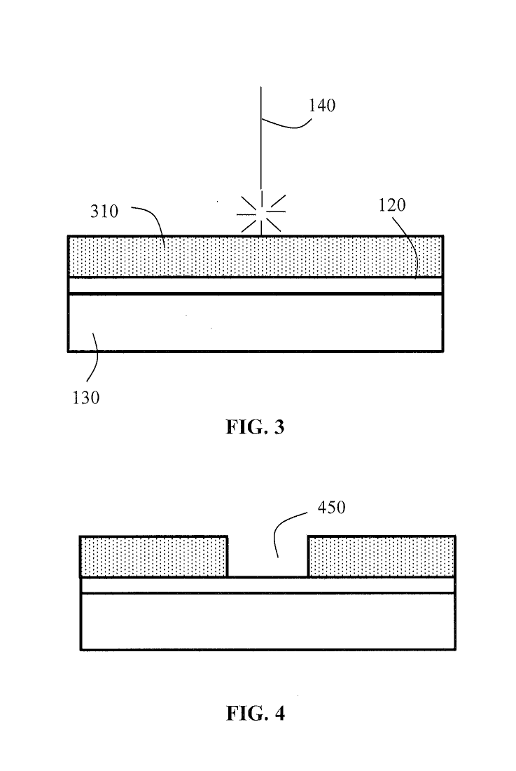

In order to improve the laser light absorption of the encapsulation/dielectric layer the encapsulation/dielectric material can be modified, as described in more detail below, thus allowing more efficient laser ablation of vias by a process that stops at the interface between encapsulation/dielectric layer and the metal and leaves the underlying metallization layer(s) substantially intact and undamaged. For example, FIGS. 3 & 4 show a schematic representation of a desirable laser ablation result for an encapsulation/dielectric layer 310 covering an electrode/metal layer 120—the underlying metal layer 120 remains substantially intact after ablation of an area of the encapsulation/dielectric layer 310 by the laser 140; the via 450 has been opened to the electrode/metal layer 120 without exposing any of the substrate/underlying layers 130. In some embodiments there may be some small amount of material from layer 310 left behind on the surface of layer 120 and substantially intact layer 120 is 70% to 100% intact, and in embodiments 90% to 100%. In some embodiments, the layer 310 may be completely removed and substantially intact layer 120 is 70% to 100% intact, and in embodiments 90% to 100% intact. After laser ablation of layer 310, electrical contact is made to electrode/metal layer 120, the electrical connection being characterized, in the case of a TFB by the presence of a desired open circuit voltage of the battery. For example, a typically good voltage range of a Li anode—LiCoO₂ thin film battery would be between 2 and 3 Volts in its as-fabricated, discharged state. Note that the presence of some residual amount of material from layer 310 and/or the removal of some amount of the electrode 120—as described above—is acceptable for a TFB providing electrical contact can be made, as described above.

In embodiments, laser ablation of transparent (in the visible and near UV wavelengths) encapsulation layer(s) such as parylene and Al₂O₃ over active metallization layer(s), while preserving the active metallization layer's integrity, is enhanced by increasing the laser light absorption within the encapsulation layer. (This is when using visible and near UV lasers, which are cheaper and easier to use than deep UV lasers, which can be technologically challenging and expensive. Some examples of lasers that may be used in embodiments described herein are 532 nm green laser, 355 nm laser, DPSS (diode-pumped solid state) pulsed picosecond and femtosecond lasers at 1064 nm, 532 nm and 355 nm.) Increasing the laser light absorption within the encapsulation layer may be in the wavelength range of 250 nm to 750 nm, in embodiments in the wavelength range of 200 nm to 1000 nm, and in embodiments in the wavelength range of 200 nm to 1064 nm.

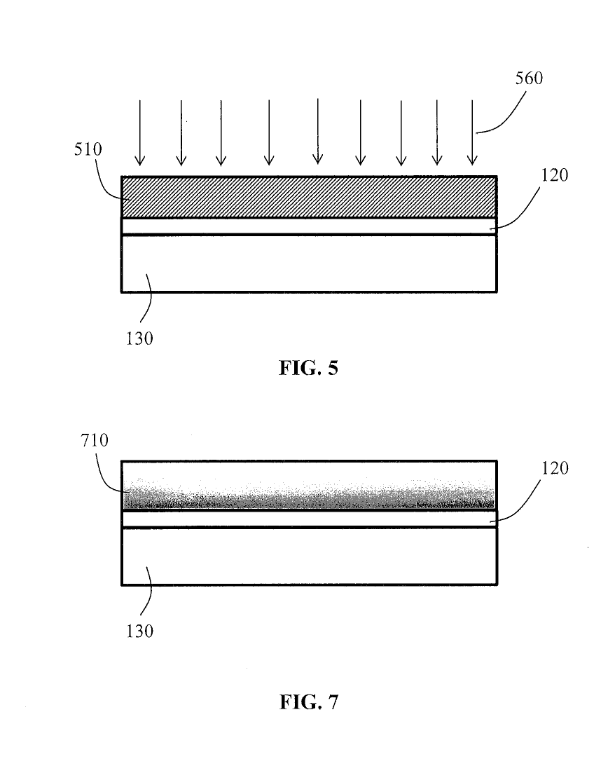

FIG. 5 is a schematic representation of a pre-ablation UV exposure 560 of an encapsulation/dielectric layer covering an electrode/metal layer 120, forming a modified encapsulation/dielectric layer 510 with improved (greater) laser energy absorption, according to some embodiments. In this example, a parylene encapsulation layer has been UV exposed, using a mercury arc lamp with higher intensity emission peaks at 365 nm, 405 nm and 436 nm to increase the laser light absorption, for example at 532 nm and 355 nm. Further examples of encapsulation/dielectric materials that can be enhanced by UV exposure for use with visible and near UV laser ablation techniques, are polyimides, aromatic polymers, Teflon and PTFE (polytetrafluoroethylene).

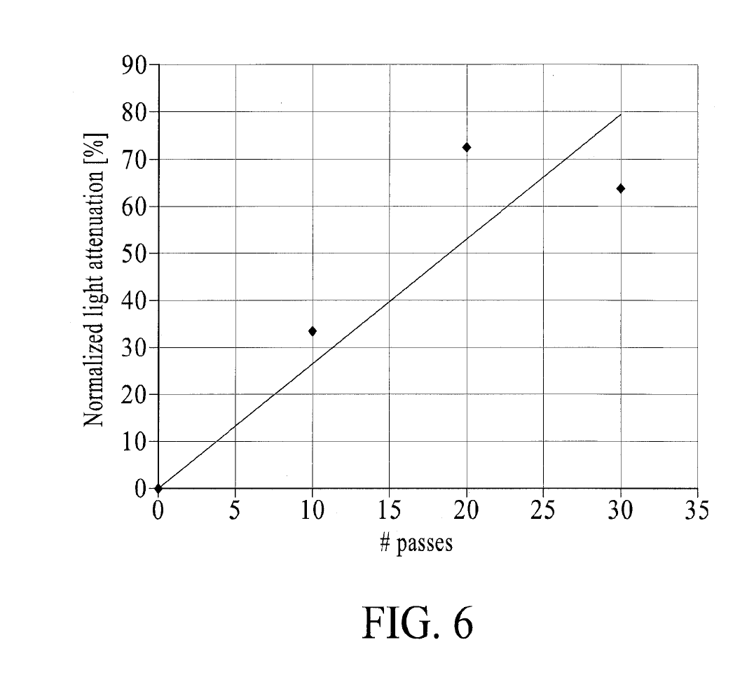

FIG. 6 shows a plot of light attenuation in the visible wavelength range against UV dose, from a mercury arc lamp with higher intensity UV emission peaks at 365 nm, 405 nm and 436 nm, for a 16 micron thick Parylene-C encapsulation layer on a 2 inch×3 inch×1 mm thick glass microscope slide, according to some embodiments. Each pass represents a UV dose of 500 mJ/cm². In some embodiments a UV dose may be used which corresponds to a point in the UV curing process approaching saturation of the light attenuation effect. This UV exposure acts to cross link and harden polymer chains resulting in a highly cross linked polymer network. Thermoset materials, such as Parylene-C, are believed to provide better humidity protection of devices since the highly cross linked polymer network provides a sufficiently torturous path for H₂O and oxygen permeation such that permeation through the encapsulation layer is effectively blocked. As an example, a layer of UV exposed parylene-C, wherein the layer is in the range of 10 microns to 20 microns thick, and wherein the dose of ultraviolet light is greater than or equal to 1 J/cm², may be utilized as the encapsulation/dielectric layer 510 described above with reference to FIG. 5.

Referring again to FIG. 3, the encapsulation/dielectric layer 310 may comprise included material to improve laser energy absorption, in some embodiments; in this example a parylene layer has been deposited with included material, such as dye, to increase the laser light absorption. The included material in embodiments is expected to improve the water vapor barrier properties of an encapsulation layer, due to: (1) plugging up of any “pores” in the layer and (2) providing a getter function, if chosen in a material property, of the dopant—for example, hygroscopic materials/dielectrics, etc. Dye doping may be accomplished by co-sublimation of a dye material and the Parylene-C thin film. The Parylene-C source dimer's sublimation temperature is approximately 150° C. A suitable sublimation dye, in embodiments, will have a similar low phase transition temperature, for example 135° C. to 149° C. Good sublimation dye candidates include solvent yellow 43, solvent red 1, solvent blue 36, etc. Ideally, the Parylene-C dimer vapor and sublimation dye vapor will incorporate into a polymer matrix upon condensation. The resultant polymer will provide the needed improvement in light absorption in the desired spectral range, e.g. the visible spectrum, to enable better laser patterning material removal. Other examples of dopants/included materials comprise: hygroscopic ceramic oxide particles such as Al₂O₃ and SiO₂; other ceramic particles; Si₃N₄; TiO₂; desiccant particles; particles such as mica flakes to slow down and block moisture and gas permeation; etc. The amount of dopants/included material may be up to percolation of about 30% (by volume) or so to act as a permeation barrier. The particle size may be much smaller than the film thickness—for example, up to a few to several microns. Furthermore, dopants may be incorporated into dielectric polymer films by the addition of dyes or other organic materials (with desirable functional groups) into the precursor material before deposition.

FIG. 7 is a schematic representation of an encapsulation/dielectric layer 710 with a compositional gradient (in the direction from the top surface of the layer to the interface with the electrode 120) to improve laser energy absorption, according to some embodiments; in this example a parylene layer has been deposited with a compositional gradient to increase the laser light absorption within the visible and near UV. A graded layer in some embodiments is a layer with a steadily changing dopant (particles and/or functional group) concentration. These dopants, particle or otherwise, would have a high(er) extinction coefficient at the desired wavelength/frequency of the laser tool which will lead to higher absorption of the laser energy and thus ablation propensity. Now, with heat absorption within the encapsulation/dielectric layer and vaporization of said layer, the parylene will be subjected to (1) heat induced ablation from the heat/absorption by the dopant, and/or (2) “bursting” of the upper portion of the parylene layer due to the pressure of the vaporized dopant material near the parylene/electrode layer interface. In some embodiments, for the purpose of stopping ablation at the interface between a polymer/dielectric layer and a lower metal layer, the compositional gradient of the polymer/dielectric layer may be configured to have a higher energy absorption at the interface where ablation is desired to stop. However, in some embodiments, for the purpose of encapsulation, a higher concentration of dopant may be desired on the top surface of the polymer, such as parylene, if the dopant is particulate in nature; the same concept applies for functional group doping if it gives a denser material (with more cross-linking, for example). In some embodiments a parylene composition gradient can be formed by deposition in a particular order of a plurality of source dimers with different optical absorption and physical properties. These source dimers can be time or temperature released at an appropriate process time. In some embodiments a plurality of separate source vaporization chambers, each with a control released dimer with different properties, may be used. These same deposition strategies may also apply for other polymers/dielectrics with compositional gradients of other dopants (functional group and particulate). For example, a dielectric material may be deposited using a plurality of source vaporization chambers, each of the plurality of source vaporization chambers vaporizing a different material, and wherein a compositional gradient is determined by controlling the relative rates, starting times, and periods of deposition of material from each of the plurality of chambers; the different materials may be parylene dimers or other dielectric materials as described herein; the controlling may be by shuttering of individual source vaporization chambers or adjusting the temperature of the material in the chamber above and below an activation temperature for vaporization.

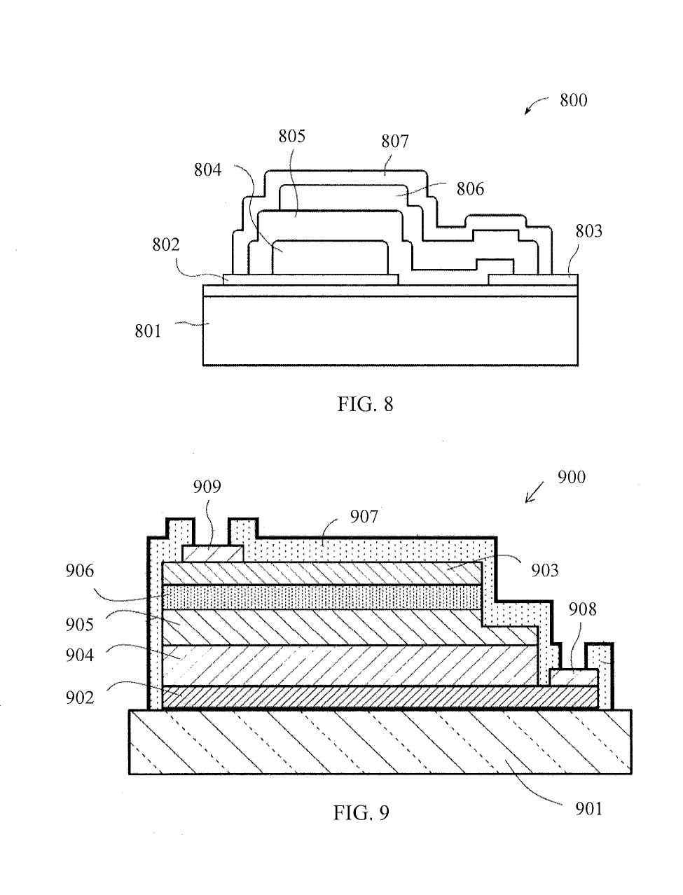

A description of TFB devices that may take advantage of embodiments of the present disclosure is provided below with reference to FIGS. 8 & 9. For example, laser ablation using a visible or near UV laser may be used to open up contact pad areas for battery electrodes through the encapsulation layer. (For example, 20 nm to 100 nm ALD AL₂O₃ plus 10 micron to 20 micron of Al₂O₃ particle doped parylene-C may be removed using laser processing to access the CCC bonding pad and the ACC bonding pad.) Note, as discussed above, that material modification may be used not only for encapsulation layers, but also for dielectric layers on metal layers within the device stack.

FIG. 8 shows a first TFB device structure 800 with cathode current collector 802 and anode current collector 803 formed on a substrate 801, followed by cathode 804, electrolyte 805 and anode 806; although the device may be fabricated with the cathode, electrolyte and anode in reverse order. Furthermore, the cathode current collector (CCC) and anode current collector (ACC) may be deposited separately. For example, the CCC may be deposited before the cathode and the ACC may be deposited after the electrolyte. The device may be covered by an encapsulation layer 807, such as parylene, to protect the environmentally sensitive layers from oxidizing agents. Note that the component layers are not drawn to scale in the TFB device shown in FIG. 7.

According to embodiments the TFB device of FIG. 8 may be fabricated by the following process: provide substrate; deposit patterned CCC; deposit patterned ACC; deposit patterned cathode; cathode anneal; deposit patterned electrolyte; deposit patterned anode; and deposit patterned encapsulation layer. Shadow masks may be used for the deposition of patterned layers. In embodiments the cathode is LiCoO₂ and the anneal is at a temperature of up to 850° C.

FIG. 9 shows a second example TFB device structure 900 comprising a substrate 901, a current collector layer 902 (e.g. Ti/Au), a cathode layer 904 (e.g. LiCoO₂), an electrolyte layer 905 (e.g. LiPON), an anode layer 906 (e.g. Li, Si), an ACC layer 903 (e.g. Ti/Au), bonding pads (Al, for example) 908 and 909 for ACC and CCC, respectively, and a blanket encapsulation layer 907 (polymer, silicon nitride, for example).

According to embodiments the TFB device of FIG. 9 may be fabricated by the following process: provide substrate; blanket deposit CCC, cathode, electrolyte, anode, and ACC to form a stack; after cathode deposition and before electrolyte deposition, anneal the cathode; laser pattern stack; deposit patterned contact pads; deposit encapsulation layer; laser pattern encapsulation layer. In some embodiments, the deposit encapsulation layer and laser pattern encapsulation layer may be repeated as needed to improve encapsulation. In embodiments the cathode is LiCoO₂ and the anneal is at a temperature of up to 850° C.

The specific TFB device structures and methods of fabrication provided above with reference to FIGS. 8 & 9 are merely examples and it is expected that a wide variety of different TFB and other electrochemical device structures and fabrication methods may benefit from the processes, structures and teaching of the present disclosure.

Furthermore, a wide range of materials may be utilized for the different TFB device layers. For example, a cathode layer may be a LiCoO₂ layer (deposited by e.g. RF sputtering, pulsed DC sputtering, etc.), an anode layer may be a Li metal layer (deposited by e.g. evaporation, sputtering, etc.), and an electrolyte layer may be a UPON layer (deposited by e.g. RF sputtering, etc.). However, it is expected that the present disclosure may be applied to a wider range of TFBs comprising different materials. Furthermore, deposition techniques for these layers may be any deposition technique that is capable of providing the desired composition, phase and crystallinity, and may include deposition techniques such as PVD, PECVD, reactive sputtering, non-reactive sputtering, RF sputtering, multi-frequency sputtering, electron and ion beam evaporation, thermal evaporation, CVD, ALD, etc.; the deposition method can also be non-vacuum based, such as plasma spray, spray pyrolysis, slot die coating, screen printing, etc. For a PVD sputter deposition process, the process may be AC, DC, pulsed DC, RF, HF (e.g., microwave), etc., or combinations thereof. Examples of materials for the different component layers of a TFB may include one or more of the following. The ACC and CCC may be one or more of Ag, Al, Au, Ca, Cu, Co, Sn, Pd, Zn and Pt which may be alloyed and/or present in multiple layers of different materials and/or include an adhesion layer of a one or more of Ti, Ni, Co, refractory metals and super alloys, etc. The cathode may be LiCoO₂, V₂O₅, LiMnO₂, Li₅FeO₄, NMC (NiMnCo oxide), NCA (NiCoAl oxide), LMO (LiₓMnO₂), LFP (LiₓFePO₄), LiMn spinel, etc. The solid electrolyte may be a lithium-conducting electrolyte material including materials such as UPON, LiI/Al₂O₃ mixtures, LLZO (LiLaZr oxide), LiSiCON, Ta₂O₅, etc. The anode may be Li, Si, silicon-lithium alloys, lithium silicon sulfide, Al, Sn, C, etc.

The anode/negative electrode layer may be pure lithium metal or may be a Li alloy, where the Li is alloyed with a metal such as tin or a semiconductor such as silicon, for example. The Li layer may be about 3 μm thick (as appropriate for the cathode and capacity balancing) and the encapsulation layer may be 3 μm or thicker. The encapsulation layer may be a multilayer of polymer/parylene and/or metal and/or dielectric, such as alumina. Other polymers that are expected to be usable as encapsulation layers in some embodiments of the present disclosure include: thereto-polymerizable materials, such as polystyrene resins, acrylic resins, urea resins, isocyante resins, and xylene resins; different forms of parylene; epoxy materials; and organic lamination layers. Other inorganic dielectrics that are expected to be usable as encapsulation layers in some embodiments of the present disclosure include: silicon oxide (SiOₓ), silicon nitride (SiNₓ), magnesium oxide (MgO), zirconium oxide (ZrO₂), zinc oxide (ZnO), and inorganic lamination layers. Note that, between the formation of the Li layer and the encapsulation layer, the part should be kept in an inert or very low humidity environment, such as argon gas or in a dry-room; however, after blanket encapsulation layer deposition the need for an inert environment will be relaxed. The ACC may be used to protect the Li layer allowing laser ablation outside of vacuum and the need for an inert environment may be relaxed.

Furthermore, the metal current collectors, both on the cathode and anode side, may need to function as protective barriers to the shuttling lithium ions. In addition, the anode current collector may need to function as a barrier to oxidants (e.g. H₂O, O₂, N₂, etc.) from the ambient. Therefore, the current collector metals may be chosen to have minimal reaction or miscibility in contact with lithium in “both directions”—i.e., the Li moving into the metallic current collector to form a solid solution and vice versa. In addition, the metallic current collector may be selected for its low reactivity and diffusivity to the oxidants from the ambient. Some potential candidates for the protective barrier to shuttling lithium ions may be Cu, Ag, Al, Au, Ca, Co, Sn, Pd, Zn and Pt. With some materials, the thermal budget may need to be managed to ensure there is no reaction/diffusion between the metallic layers. If a single metal element is incapable of functioning as both a protective barrier to shuttling lithium ions and to oxidants, then alloys may be considered, also, dual (or multiple) layers may be used. Furthermore, in addition an adhesion layer may be used in combination with a layer of one of the aforementioned refractory and non-oxidizing layers—for example, a Ti adhesion layer in combination with Au. The current collectors may be deposited by (pulsed) DC sputtering of metal targets (approximately 300 nm) to form the layers (e.g., metals such as Cu, Ag, Pd, Pt and Au, metal alloys, metalloids or carbon black). Furthermore, there are other options for forming the protective barriers to the shuttling lithium ions, such as dielectric layers, etc.

Although embodiments of the present disclosure have been described herein with reference to specific examples of TFB devices and process flows, the teaching and principles of the present disclosure may be applied to a wider range of TFB devices and process flows. For example, devices and process flows are envisaged for TFB stacks which are inverted from those described previously herein—the inverted stacks having ACC and anode on the substrate, followed by solid state electrolyte, cathode, CCC and encapsulation layer. Furthermore, those of ordinary skill in the art would appreciate how to apply the teaching and principles of the present disclosure to generate a wide range of devices and process flows,

Although embodiments of the present disclosure have been described herein with reference to TFBs, the teaching and principles of the present disclosure may also be applied to improved devices and process flows for other electrochemical devices, including electrochromic devices, although electrochromic devices will have the added constraint that the devices be transparent in the visual spectrum. In the latter case, a near UV laser may be used for ablation of encapsulation/dielectric layer and it is expected that the near UV light absorption may be enhanced using the methods described above without increasing light absorption within the visible spectrum. Those of ordinary skill in the art would appreciate how to apply the teaching and principles of the present disclosure to generate devices and process flows which are specific to other electrochemical devices.

Although embodiments of the present disclosure have been particularly described with reference to certain embodiments thereof, it should be readily apparent to those of ordinary skill in the art that changes and modifications in the form and details may be made without departing from the spirit and scope of the disclosure.

What is claimed is:

1. A method of fabricating an electrochemical device, comprising:
providing a layer of dielectric material on a metal electrode;
enhancing light absorption in said layer of dielectric material within the visible and near UV range, forming a layer of enhanced dielectric material; and
laser ablating said enhanced dielectric material in select areas of said layer using a laser with a wavelength in the visible and near UV range, wherein said laser ablating leaves said metal electrode substantially intact.

2. The method as in claim 1, wherein said laser ablating removes less than 30% of the thickness of said metal electrode.

3. The method as in claim 1, wherein said layer of dielectric material is an encapsulation layer.

4. The method as in claim 1, wherein said dielectric material comprises a thermoset polymer.

5. The method as in claim 1, wherein said enhancing light absorption comprises ultraviolet light exposure of said dielectric material.

6. A method of fabricating an electrochemical device, comprising:
providing a layer of dielectric material on a metal electrode, said layer being engineered for higher laser light absorption within the visible and near ultraviolet range; and
laser ablating said dielectric material in select areas of said layer using a laser with a wavelength in the visible and near UV range, wherein said laser ablating leaves said metal electrode substantially intact.

7. The method as in claim 6, wherein said layer of dielectric material has a compositional gradient in the direction from the top of said layer to the interface between said layer and said metal electrode.

8. The method as in claim 7, wherein said dielectric material is deposited using a plurality of source vaporization chambers, each of said plurality of source vaporization chambers vaporizing a different material, and wherein said compositional gradient is determined by controlling the relative rates, starting times, and periods of deposition of material from each of said plurality of chambers.

9. The method as in claim 7, wherein said layer of dielectric material comprises parylene and inorganic particles.

10. The method as in claim 7, wherein said layer of dielectric material comprises parylene and an organic dye in the visible optical range.

11. An electrochemical device comprising:
a substrate;
a stack of device layers formed on said substrate, said stack comprising a cathode current collector layer, a cathode layer, an electrolyte layer, an anode layer and an anode current collector layer; and
an encapsulation layer covering said stack, said encapsulation layer being engineered to strongly absorb laser light within the visible and near ultraviolet range.

12. The electrochemical device of claim 11, wherein said encapsulation layer comprises ultraviolet light cross-linked polymer.

13. The electrochemical device of claim 11, wherein said encapsulation layer comprises dielectric material with a compositional gradient in the direction from the top of said encapsulation layer to the interface between said encapsulation layer and said metal electrode.

14. The electrochemical device of claim 11, wherein said encapsulation layer comprises parylene and inorganic particles.

15. The electrochemical device of claim 11, wherein said encapsulation layer comprises parylene and an organic dye in the visible optical range.
